(19) United States
(12) Patent Application Publication
(10) Pub. No.: US 2026/0098911 A1
(43) Pub. Date: Apr. 9, 2026

(54) PREDICTING OF A BATTERY ISSUE OF A VEHICLE WITH MULTIPLE BATTERIES

(71) Applicant: CPS Technology Holdings LLC, New York, NY (US)

(72) Inventors: Cagatay TOPCU, Milwaukee, WI (US); Chad Michael STEIGHNER, Sussex, WI (US); Jeffrey R. PAYNTER, Colgate, WI (US)

(21) Appl. No.: 19/120,872

(22) PCT Filed: Oct. 19, 2023
(86) PCT No.: PCT/US2023/077269

§ 371 Date: Apr. 14, 2025

Related U.S. Application Data
(60) Provisional application No. 63/417,547, filed on Oct. 19, 2022.

(51) Int. Cl. G01R 31/392; B60L 58/16; B60L 58/18; G01R 31/36; G01R 31/371; G01R 31/3832; G01R 31/396; H01M 10/42

(52) U.S. Cl. CPC G01R 31/392; B60L 58/16; B60L 58/18; G01R 31/3647; G01R 31/371; G01R 31/3832; G01R 31/396; H01M 10/4207; H01M 10/425; H01M 2010/4271; H01M 2010/4278

(57) ABSTRACT

A battery device removably connectable at least to a first battery and a second battery is described. The battery device includes processing circuitry configured to determine a battery health condition of the first battery based at least in part on a plurality of first data samples, a plurality of second data samples, a plurality of third data samples, a plurality of fourth data samples, and a first spread. The plurality of first data samples is associated with the first sensor and a first electrical parameter of the first battery. The plurality of second data samples is associated with the first sensor and a second electrical parameter of the first battery. The plurality of third data samples is associated with the second sensor and a third electrical parameter of the second battery. One or more actions are performed based on the determination of the battery health condition.

### TECHNICAL FIELD

This disclosure relates to a method and system for prediction of a health condition of an energy storage module (e.g., battery).

### BACKGROUND

Motor-powered and/or electrically powered vehicles tend to rely on using one or more battery systems for providing a starting power (e.g., power used to crank and start an engine) and/or at least a portion of a motion power for the vehicle. Such vehicles may include one or more of an air-or watercraft, a rail-guided vehicle, a street vehicle, etc., where a street vehicle may refer to, for example, cars, trucks, buses, recreational vehicles, etc.

In vehicles, different types of batteries (e.g., energy storage modules) are used, such as traction batteries (for electric or hybrid electric vehicles) and starter batteries. In automotive applications, for example, a starter battery is used for providing the necessary energy/power required for starting a vehicle, while a traction battery may generally refer to a battery which provides motive power to the vehicle, for example.

As battery technology evolves, the demand for improved power sources such as energy storage modules (e.g., batteries, battery cells, etc.) for vehicles continues to grow. However, some batteries tend to be very susceptible to battery health degradation, which may negatively affect components of the energy storage module. For example, battery health may degrade over time, e.g., where the degradation of the battery health goes unnoticed until a battery/system failure occurs.

In some cases, a battery pack of two or more batteries may be used to start/crank an engine of a truck. The battery health of one battery in the battery pack may degrade faster than the battery health of the other batteries of the battery pack. As all the batteries in the battery pack may be used for starting/cranking the engine of the truck, the degradation of the one battery may not detected before the battery fails. The undetected degradation may also cause damage to systems such as the starting motor.

In other words, existing battery-based systems lack battery management processes and/or components that adequately detect degradation of battery health (e.g., of a battery in a battery pack) before battery/system failure occurs.

### SUMMARY

Some embodiments advantageously provide a method and system for prediction of a health condition of an energy storage module (e.g., battery).

According to an aspect, a battery device is removably connectable at least to a first battery and a second battery. The battery device comprises processing circuitry configured to determine a battery health condition of the first battery based at least in part on at least one of a first electrical parameter of the first battery and a second electrical parameter of the second battery; and at least one of a third electrical parameter of the first battery and a fourth electrical parameter of the second battery.

According to another aspect, a method in a battery device removably connectable at least to a first battery and a second battery is described. The method comprises determining a battery health condition of the first battery based at least in part on at least one of a first electrical parameter of the first battery and a second electrical parameter of the second battery; and at least one of a third electrical parameter of the first battery and a fourth electrical parameter of the second battery.

According to one aspect, a system is described. The system comprises a first battery; a second battery electrically connected to the first battery; and a battery device removably connectable at least to the first battery and the second battery, the battery device comprising processing circuitry configured to measure a first electrical parameter of the first battery and a second electrical parameter of the second battery, where each one of the first and second electrical parameters includes a first plurality of electrical parameter samples, and each electrical parameter sample of the first plurality of peak current samples is measured during one cranking action. The processing circuitry is further configured to determine an ignition status associated with the first and second batteries; determine a battery health condition of the first battery based at least in part on at least one of the first electrical parameter of the first battery and the electrical parameter of the second battery; and at least one of a third electrical parameter of the first battery and a fourth electrical parameter of the second battery when the ignition status is off. The processing circuitry is also configured to determine at least one of a first spread and a second spread, where each one of the first and second spreads is between the first electrical parameter and the second electrical parameter, and the first and second spreads correspond to a first interval of time and a second interval of time, respectively; and forecast the battery health condition is expected to occur in a future time interval based on a spread rate of change of the first and second spreads.

According to one aspect, a battery device removably connectable at least to a first battery and a second battery is described. The battery device includes processing circuitry, a first sensor and a second sensor. The first sensor and the second sensor are in communication with the processing circuitry. The processing circuitry is configured to determine a battery health condition of the first battery based at least in part on a plurality of first data samples, a plurality of second data samples, a plurality of third data samples, a plurality of fourth data samples, and a first spread. The plurality of first data samples is associated with the first sensor and a first electrical parameter of the first battery. The plurality of second data samples is associated with the first sensor and a second electrical parameter of the first battery. The plurality of third data samples is associated with the second sensor and a third electrical parameter of the second battery. The plurality of fourth data samples is associated with the second sensor and a fourth electrical parameter of the second battery. The first spread is associated with the plurality of first data samples and the plurality of third data samples. The processing circuitry is further configured to perform one or more actions based on the determination of the battery health condition.

In some embodiments, the first sensor is configured to perform one or more measurements of the first electrical parameter and the second electrical parameter of the first battery. The second sensor is configured to perform one or more measurements of and the fourth electrical parameter of the second battery.

In some other embodiments, the processing circuitry is further configured to determine the plurality of first data samples based on the one or more measurements of the first electrical parameter, determine the plurality of second data samples based on the one or more measurements of the second electrical parameter, determine the plurality of third data samples based on the one or more measurements of the third electrical parameter, and determine the plurality of fourth data samples based on the one or more measurements of the fourth electrical parameter.

In some embodiments, the first electrical parameter and the third electrical parameter are measured during one cranking action.

In some other embodiments, the processing circuitry is further configured to determine the first spread. The first spread is a difference between at least one first data sample of the plurality of first data samples and at least one third data sample of the plurality of third data samples.

In some embodiments, a first distribution density (e.g., determined by the processing circuitry) of the at least one first data sample is greater than a first distribution density threshold. A third distribution density (e.g., determined by the processing circuitry) of the at least one third data sample is greater than a third distribution density threshold.

In some other embodiments, the processing circuitry is further configured to determine the battery health condition of the first battery further based on a second spread.

In some embodiments, the processing circuitry is further configured to at least one of determine a first group of data samples of the plurality of second data samples that exceeds a predetermine electrical parameter threshold, determine a second group of data samples of the plurality of fourth data samples that exceeds the predetermine electrical parameter threshold, and determine the second spread. The second spread is between at least one data sample of the first group and another data sample of the second group.

In some other embodiments, the first group of data samples and the second group of data samples correspond to a first ignition status. The first ignition status is off.

In some embodiments, the processing circuitry is further configured to determine a battery charging condition exists based on the second spread. The battery charging condition is inconsistent with the first ignition status being off, and the determined battery health condition is further based on the determined battery charging condition.

In some other embodiments, the processing circuitry is further configured to at least one of: (A) compare at least one data sample of the first group of data samples with at least one other data sample of at least one of the plurality of second data samples and the plurality of fourth data samples, where the one other data sample corresponds to a second ignition status, and the second ignition status is on; and (B) confirm that the battery health condition of the first battery exists based on the comparison, the battery charging condition, the first spread, and the second spread.

In some embodiments, the processing circuitry is further configured to at least one of determine a first spread rate of change based on the first spread, determine a second spread rate of change based on the second spread, forecast the battery health condition is expected to occur within a future time interval based on at least one of the first spread rate of change and the second spread rate of change.

In some other embodiments, performing the one or more actions includes one or more of determining a maintenance action to address the battery health condition, transmitting an indication of at least one of the battery health condition and the maintenance action, and causing a battery management system of the first battery to disable the first battery.

In some embodiments, the first electrical parameter of the first battery is peak current, the second electrical parameter of the first battery is battery total current, the third electrical parameter of the second battery is peak current, and the fourth electrical parameter of the second battery is battery total current.

According to another aspect, a method in a battery device removably connectable at least to a first battery and a second battery is described. The battery device includes a first sensor and a second sensor. The method includes determining a battery health condition of the first battery based at least in part on a plurality of first data samples, a plurality of second data samples, a plurality of third data samples, a plurality of fourth data samples, and a first spread. The plurality of first data samples is associated with the first sensor and a first electrical parameter of the first battery. The plurality of second data samples is associated with the first sensor and a second electrical parameter of the first battery. The plurality of third data samples is associated with the second sensor and a third electrical parameter of the second battery. The plurality of fourth data samples is associated with the second sensor and a fourth electrical parameter of the second battery. The first spread is associated with the plurality of first data samples and the plurality of third data samples. The method further includes performing one or more actions based on the determination of the battery health condition.

In some embodiments, the method further includes performing, by the first sensor, one or more measurements of the first electrical parameter and the second electrical parameter of the first battery and performing, by the second sensor, one or more measurements of and the fourth electrical parameter of the second battery.

In some other embodiments, the method further includes determining the plurality of first data samples based on the one or more measurements of the first electrical parameter, determining the plurality of second data samples based on the one or more measurements of the second electrical parameter, determining the plurality of third data samples based on the one or more measurements of the third electrical parameter, and determining the plurality of fourth data samples based on the one or more measurements of the fourth electrical parameter.

In some embodiments, the first electrical parameter and the third electrical parameter are measured during one cranking action.

In some other embodiments, the method further includes determining the first spread, the first spread being a difference between at least one first data sample of the plurality of first data samples and at least one third data sample of the plurality of third data samples.

In some embodiments, a first distribution density (e.g., determined as part of the method) of the at least one first data sample is greater than a first distribution density threshold, and a third distribution density (e.g., determined as part of the method) of the at least one third data sample is greater than a third distribution density threshold.

In some other embodiments, the method further includes determining the battery health condition of the first battery further based on a second spread.

In some embodiments, the method further includes at least one of determining a first group of data samples of the plurality of second data samples that exceeds a predetermine electrical parameter threshold, determining a second group of data samples of the plurality of fourth data samples that exceeds the predetermine electrical parameter threshold, and determining the second spread. The second spread is between at least one data sample of the first group and another data sample of the second group.

In some other embodiments, the first group of data samples and the second group of data samples correspond to a first ignition status. The first ignition status is off.

In some embodiments, the method further includes determining a battery charging condition exists based on the second spread, where the battery charging condition is inconsistent with the first ignition status being off. The determined battery health condition is further based on the determined battery charging condition.

In some other embodiments, the method further includes at least one of comparing at least one data sample of the first group of data samples with at least one other data sample of at least one of the plurality of second data samples and the plurality of fourth data samples. The one other data sample corresponds to a second ignition status, and the second ignition status is on. The method also includes confirming that the battery health condition of the first battery exists based on the comparison, the battery charging condition, the first spread, and the second spread.

In some embodiments, the method further includes at least one of determining a first spread rate of change based on the first spread, determining a second spread rate of change based on the second spread, and forecasting the battery health condition is expected to occur within a future time interval based on at least one of the first spread rate of change and the second spread rate of change.

In some embodiments, performing the one or more actions includes determining a maintenance action to address the battery health condition, transmitting an indication of at least one of the battery health condition and the maintenance action, and causing a battery management system of the first battery to disable the first battery.

In some other embodiments, the first electrical parameter of the first battery is peak current, the second electrical parameter of the first battery is battery total current, the third electrical parameter of the second battery is peak current, and the fourth electrical parameter of the second battery is battery total current.

According to one aspect, a system is described. The system includes a first battery, a second battery electrically connected to the first battery, and a battery device. The battery device is removably connectable at least to the first battery and the second battery. The battery device includes processing circuitry, a first sensor and a second sensor. The first sensor and the second sensor are in communication with the processing circuitry. The processing circuitry is configured to determine a battery health condition of the first battery based at least in part on a plurality of first data samples, a plurality of second data samples, a plurality of third data samples, a plurality of fourth data samples, and a first spread. The plurality of first data samples is associated with the first sensor and a first electrical parameter of the first battery. The plurality of second data samples is associated with the first sensor and a second electrical parameter of the first battery. The plurality of third data samples is associated with the second sensor and a third electrical parameter of the second battery. The plurality of fourth data samples is associated with the second sensor and a fourth electrical parameter of the second battery. The first spread is associated with the plurality of first data samples and the plurality of third data samples. The processing circuitry is further configured to forecast the battery health condition is expected to occur within a future time interval based at least one the first spread and an interval of time associated with the spread and perform one or more actions based on the determination of the battery health condition.

In some embodiments, the first sensor is configured to perform one or more measurements of the first electrical parameter and the second electrical parameter of the first battery. The second sensor is configured to perform one or more measurements of and the fourth electrical parameter of the second battery.

### BRIEF DESCRIPTION OF THE DRAWINGS

A more complete understanding of embodiments described herein, and the attendant advantages and features thereof, will be more readily understood by reference to the following detailed description when considered in conjunction with the accompanying drawings wherein:

FIG. 1 is a diagram of an example system according to principles disclosed herein;

FIG. 2 shows an example battery constructed in accordance with the principles of the present disclosure;

FIG. 3 is a block diagram of some entities in the system according to some embodiments of the present disclosure;

FIG. 4 shows an example battery device and four batteries in parallel according to some embodiments of the present disclosure;

FIG. 5 is a flowchart of an example process in a battery device according to some embodiments of the present disclosure;

FIG. 6 is a flowchart of another example process in a battery device according to some embodiments of the present disclosure;

FIG. 7 shows a distribution chart of example peak current during cranking when all batteries are healthy according to some embodiments of the present disclosure;

FIG. 8 shows another distribution chart of example peak current during cranking where early signs of battery issues are detected according to some embodiments of the present disclosure;

FIG. 9 shows another distribution chart of example peak current during cranking where battery issues are detected according to some embodiments of the present disclosure;

FIG. 10 shows distribution charts of example battery total current when all batteries are healthy and the ignition status of the vehicle is off according to some embodiments of the present disclosure;

FIG. 11 shows distribution charts of example battery total current when all batteries are healthy according and the ignition status of the vehicle is on to some embodiments of the present disclosure; and

FIG. 12 shows a distribution chart of example battery total current when the ignition is off and at least one battery has an issue according to some embodiments of the present disclosure; and

FIG. 13 shows the distribution chart of example battery total current when the ignition is on and at least one battery has an issue.

### DETAILED DESCRIPTION

Before describing in detail exemplary embodiments, it is noted that the embodiments reside primarily in combinations of apparatus components and processing steps related to prediction of a health condition of an energy storage module (e.g., battery). Accordingly, the system and method components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

As used herein, relational terms, such as “first” and “second,” “top” and “bottom,” and the like, may be used solely to distinguish one entity or element from another entity or element without necessarily requiring or implying any physical or logical relationship or order between such entities or elements. The terminology used herein is for the purpose of describing particular embodiments only and is not intended to be limiting of the concepts described herein. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

In some embodiments, the term “parameter” refers to any parameter related to battery performance, management, operation, vehicle parameters (e.g., ignition status), etc., as well as performance, management, operation, etc., of the device in which the battery is installed. In some embodiments the parameter may be an electrical parameter such as voltage, current (e.g., peak current, total current, maximum current, minimum current, peak voltage, total voltage, dropped voltage, minimum voltage, maximum voltage, etc.), state of charge, resistance value (e.g., an internal resistance value indicating a possible internal short circuit) and/or any other parameter such as temperature, pressure, etc. The parameter may be measured/determined. F Further, the parameter may be associated with a battery, battery component, vehicle (or any other system), load associated with the battery, etc. A parameter threshold may refer to a threshold associated with a parameter.

A battery health condition may refer to any condition associated with a battery (and/or devices, systems, components associated with the battery such as health of the battery and/or of a vehicle/vehicle system). A battery health condition may include a failure (e.g., a catastrophic failure of a battery/system, a potential failure, a condition associated with a potential failure, triggered system failures, battery pack failure, fail to start/operate vehicle, etc.), a degradation condition (e.g., inability to meet a user/functional/specification requirement such as when a parameter is under/over a predetermined threshold), an internal short circuit, an internal resistance value being under a predetermined threshold (e.g. indicating a short circuit condition), etc.

Spread in the embodiments of the present disclosure may refer to a spread/separation between curves and/or a difference (spread/separation) between at least a point of a curve and at least another point of another curve. For example, spread may include the difference/separation between two or more curves and/or points of each curve. Spread may also include a difference/separation between points of a same curve. A curve may refer to a group of data samples (or group of points or group of data points) in a graph, where the group of data samples correspond to a parameter or parameter value that is determined, measured, estimated, collected, etc.

An operation mode may refer to one or more modes of operating a battery (and/or BMS and/or associated vehicle/system). The operation mode may be based on one parameter such state of charge of the battery.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In embodiments described herein, the joining term, “in communication with” and the like, may be used to indicate electrical or data communication, which may be accomplished by physical contact, induction, electromagnetic radiation, signaling such as radio signaling, infrared signaling or optical signaling, for example. One having ordinary skill in the art will appreciate that multiple components may interoperate, and modifications and variations are possible of achieving the electrical and data communication.

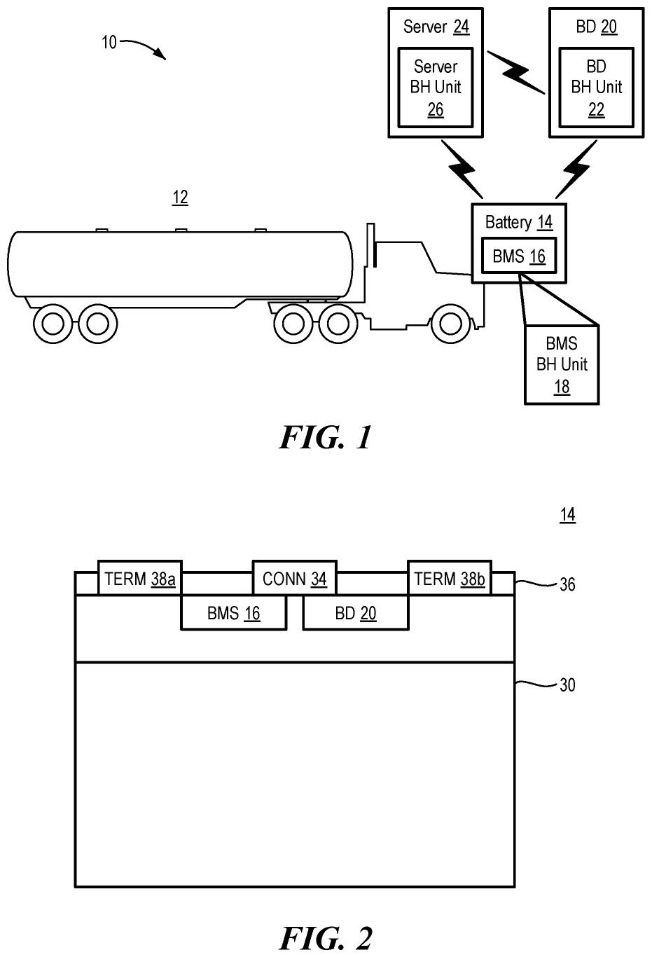

Referring to the drawing figures, in which like elements are referred to by like reference numerals, there is shown in FIG. 1 a diagram of a system 10, according to an embodiment, which comprises one or more vehicles 12, e.g., a truck. The vehicle 12 comprises battery 14 for powering at least one function of vehicle 12. Battery 14 may be a lithium-ion based battery that includes one or more energy storage modules. Although a lithium-ion based battery has been described, the teachings described herein are equally applicable to other battery types. Battery 14 may include one or more batteries such as a first battery 14a, second battery 14b, third battery 14c, fourth battery 14d, etc., e.g., electrically connected (e.g., in parallel, series, etc.) as part of a battery pack. Battery 14 includes battery management system (BMS) 16 that is configured to perform one or more battery management functions. In some embodiments, the BMS 16 may measure/determine certain battery parameters, e.g., current such as peak current and/or total current, state of charge (SOC), voltage, etc., and transmit/receive data (and/or signals such as control signals) to/from another system/device. A BMS 16 is configured to include a BMS battery health (BH) unit 18 that may be configured to perform one or more functions as described herein such as determining a battery health condition of battery 14.

System 10 may further include battery device (BD) 20 comprising BD BH unit 22 that may be configured to perform one or more functions as described herein such as determining a battery health condition of battery 14, predict the battery health condition may occur at a future time, etc. System 10 may also include server 24 comprising server BH unit 26, which may be configured to perform one or more functions as described herein such as determining a battery health condition of battery 14, schedule a maintenance action based on the determined battery health condition, etc.

It is contemplated that one or more entities of system 10 are in communication with each other via one or more of wireless communication, power communication, wired communication, via one or more networks, etc. For example, vehicle 12, battery 14, BD 20, and server 24 may communicate with each other directly or indirectly using wireless communication, power communication, wired communication, etc. Further, while it may be assumed in one or more embodiments that there is not data or signal communication between battery 14 and vehicle 12, the embodiments described herein are equally applicable to vehicles 12 where there are some data/signal communications between battery 14 and vehicle 12.

FIG. 2 shows an example battery 14 constructed in accordance with the principles of the present disclosure. Battery 14 includes a housing 30 into which one or more battery components may be positioned. The components may be electrically interconnected (not shown in the FIGS.), such as via an electrically conductive bus bar system which electrically interconnects the components in an electrically serial, electrically parallel or combination of electrically serial and parallel manner, depending on the intended voltage and current requirements.

A battery monitoring system (BMS) 16 may be included. BMS 16 may include a monitoring connector 34 that allows for a removable external connection any other component of system 10 (e.g., to the vehicle's data bus, to some other communication device, BD 20, etc.) and/or internal connection, e.g., any components of battery 14 and/or BMS 16 and/or BD 20. Connector 34 may be comprised in BMS 16 and/or BD 20 and/or battery 14. In some embodiments, connector 34 may be configured to removably couple and/or connect (electrically, physically) to another connector (e.g., coupled to BMS 16). The monitoring connector 34 can, in some embodiments, be integrated with the housing 30, such as in a cover 36 of the housing 30. Battery 14 also includes terminals, such as a positive terminal 38a and a negative terminal 38b (collectively referred to as terminals 38) to provide the contact points for electrical connection of the battery 14 (e.g., to BD 20, to the vehicle 12 to provide power to the vehicle and/or BMS 16 to power BMS 16). Terminals 38 may be arranged to protrude through housing 30, such as protruding through cover 36. Terminals 38 may be electrically connected to the bus bars inside housing 30 and/or directly connected to the cells (bus bars and direct connection not shown). Terminals 38 may be arranged to receive and/or couple to BD 20 and/or a component of BD 20 (e.g., a sensor) such as to power BD 20 and/or its component, for the BD 20 to measure a battery parameter, etc. In some embodiments, BD 20 (e.g., sensor) may be electrically coupled to one or more of terminals 38 and a vehicle component (e.g., starter) which is also connected to and powered by battery 14. That is, BD 20 may be part of an electric circuit and configured to measure a parameter of the electric circuit, such as current (e.g., peak current, total current, etc.) or any other parameter.

Further, battery 14 may be arranged to provide many power capacities and physical sizes, and to operate under various parameters and parameter ranges. It is also noted that implementations of battery 14 some can be scaled to provide various capacities. For example, in some embodiments, the power capacity of battery 14 can range from 25 Ah to 75 Ah. It is noted, however, that this is range is merely an example, and that it is contemplated that embodiments of battery 14 can be arranged to provide less than a 25 Ah capacity or more than a 75 Ah capacity. Power capacity scaling can be accomplished, for example, by using higher or lower power capacity cells in the housing 21, and/or by using fewer or more cells in the housing 30. In some embodiments, battery 14 may be incorporated as part of a vehicle such as an electric vehicle (EV) or another type of vehicle where battery power is needed. Other electrical parameters of the battery 14 can be adjusted/accommodated by using components that may cumulatively have the desired operational characteristics, e.g., current, voltage, charging capacity/rate, discharge rate, etc. Thermal properties can be managed based on components characteristics, the use of heat sinks and/or thermal energy discharge plates, etc., within or external to the housing 30.

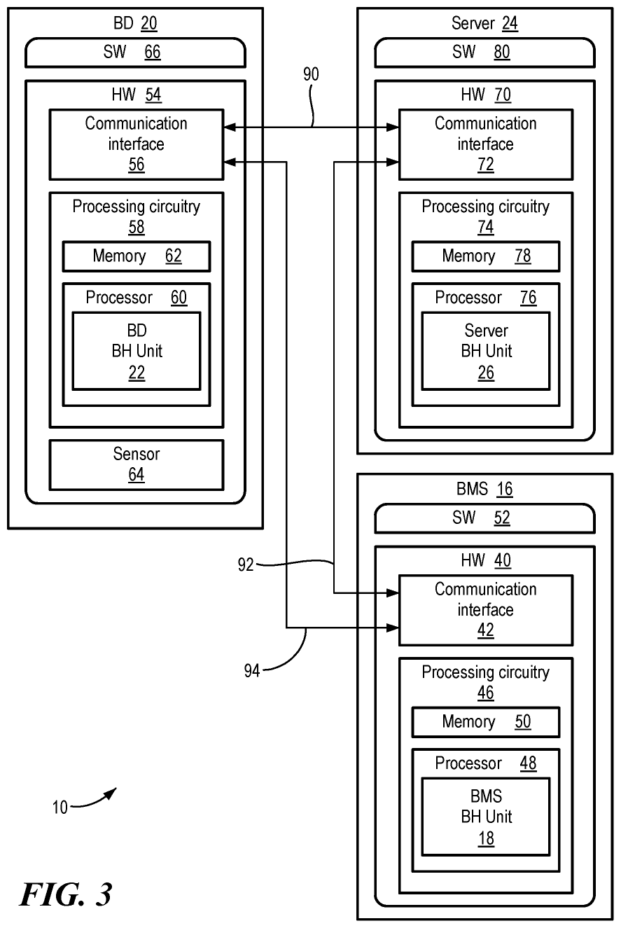

Example implementations, in accordance with an embodiment, of BMS 16, BD 20, and server 24 discussed in the preceding paragraphs will now be described with reference to FIG. 3. BMS 16 may have hardware 40 that may include a communication interface 42 that is configured to communication with one or more entities in system 10 via wired and/or wireless communication. The communication may be protocol based communications.

The hardware 40 includes processing circuitry 46. The processing circuitry 46 may include a processor 48 and memory 50. In particular, in addition to or instead of a processor, such as a central processing unit, and memory, the processing circuitry 46 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 48 may be configured to access (e.g., write to and/or read from) memory 50, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

Thus, the BMS 16 may further comprise software 52, which is stored in, for example, memory 50, or stored in external memory (e.g., database, etc.) accessible by the BMS 16. The software 52 may be executable by the processing circuitry 46.

The processing circuitry 46 may be configured to control any of the methods and/or processes described herein and/or to cause such methods, and/or processes to be performed, e.g., by BMS 16. The processor 48 corresponds to one or more processors 48 for performing BMS 16 functions described herein. The BMS 16 includes memory 50 that is configured to store data, programmatic software code and/or other information described herein. In some embodiments, the software 52 may include instructions that, when executed by the processor 48 and/or processing circuitry 46, causes the processor 48 and/or processing circuitry 46 to perform the processes described herein with respect to BMS 16. For example, the processing circuitry 46 of the BMS 16 may include BMS BH unit 18 that is configured to perform any step and/or task and/or process and/or method and/or feature described in the present disclosure, e.g., determine a battery health condition. While BMS BH unit 18 is illustrated as being part of BMS 16, BMS BH unit 18 and associated functions described herein may be implemented in a device separate from BMS 16 such as in battery 14 or another device.

BD 20 may have hardware 54 that may include a communication interface 56 that is configured to communicate with one or more entities in system 10 (and/or outside of system 10) via wired and/or wireless communication. The communication may be protocol based communication.

The hardware 54 includes processing circuitry 58. The processing circuitry 58 may include a processor 60 and memory 62. In particular, in addition to or instead of a processor, such as a central processing unit, and memory, the processing circuitry 58 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 60 may be configured to access (e.g., write to and/or read from) memory 62, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

BD 20 may further comprise software 66, which is stored in, for example, memory 62, or stored in external memory (e.g., database, etc.) accessible by the BD 20. The software 66 may be executable by the processing circuitry 58.

The processing circuitry 58 may be configured to control any of the methods and/or processes described herein and/or to cause such methods, and/or processes to be performed, e.g., by BD 20. The processor 60 corresponds to one or more processors 60 for performing BD 20 functions described herein. The BD 20 includes memory 62 that is configured to store data, programmatic software code and/or other information described herein. In some embodiments, the software 66 may include instructions that, when executed by the processor 60 and/or processing circuitry 58, causes the processor 60 and/or processing circuitry 58 to perform the processes described herein with respect to BD 20. For example, the processing circuitry 58 of the BD 20 may include BD BH unit 22 configured to perform any step and/or task and/or process and/or method and/or feature described in the present disclosure, e.g., determine a battery health condition. BD 20 may also include sensor 64 configured to measure/determine at least one parameter, e.g., associated with battery 14. The at least one parameter may include current such as peak current, total current, etc. Peak current may include current associated with current flow experienced within a motor and/or associated circuit during a predetermined interval of time following the energizing (switching on) of the motor, e.g., current associated with cranking of an engine, current associated with operating a starter motor of an engine, etc. However, peak current is not limited as such and may be other types of current. Although sensor 64 is shown as a part of BD 20, sensor 64 is not limited as such, and may be part of BMS 16 and/or server 24 or any other component and/or a standalone sensor.

Further, server 24 includes hardware 70, and the hardware 28 may include a communication interface 72 for performing wired and/or wireless communication with BMS 16 and/or BD 20 and/or any other device. For example, communication interface 72 of server 24 may communicate with communication interface 56 of BD 20 via communication link 90. In addition, communication interface 72 of server 24 may communicate with communication interface 42 of BMS 16 via communication link 92. Similarly, communication interface 42 may communicate with communication interface 56 via communication link 94. At least one of communication links 90, 92, 94 may refer to a wired/wireless connection (such as WiFi, Bluetooth, etc.).

In the embodiment shown, the hardware 70 of server 24 includes processing circuitry 74. The processing circuitry 74 may include a processor 76 and a memory 78. In particular, in addition to or instead of a processor, such as a central processing unit, and memory, the processing circuitry 74 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 76 may be configured to access (e.g., write to and/or read from) the memory 78, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

Thus, the server 24 further has software 80 stored internally in, for example, memory 78, or stored in external memory (e.g., database, etc.) accessible by the server 24 via an external connection. The software 80 may be executable by the processing circuitry 74. The processing circuitry 74 may be configured to control any of the methods and/or processes described herein and/or to cause such methods, and/or processes to be performed, e.g., by server 24. Processor 76 corresponds to one or more processors 76 for performing server 24 functions described herein. The memory 78 is configured to store data, programmatic software code and/or other information described herein. In some embodiments, the software 80 may include instructions that, when executed by the processor 76 and/or processing circuitry 74, causes the processor 76 and/or processing circuitry 74 to perform the processes described herein with respect to server 24. For example, processing circuitry 74 of server 24 may include server BH unit 26 that is configured to perform one or more server 24 functions as described herein, e.g., selecting one or more operation modes.

In some embodiments, BD 20 may be comprised in a BMS 16 and/or battery 14 and/or be standalone. In some other embodiments, BD 20 may be configured to perform any BMS function and/or be a BMS 16.

Although FIGS. 1 and 3 show one or more “units” such as BMS BH unit 18, BD BH unit 22, server BH unit 26 as being within a respective processor, it is contemplated that these units may be implemented such that a portion of the unit is stored in a corresponding memory within the processing circuitry. In other words, the units may be implemented in hardware, software or in a combination of hardware and software within the processing circuitry.

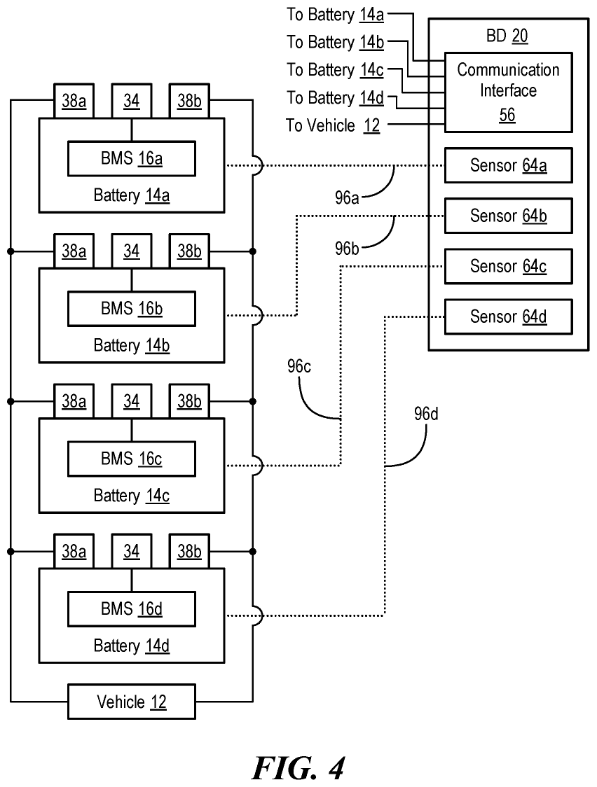

FIG. 4 shows an example battery device and four batteries 14 in parallel according to some embodiments of the present disclosure. More specifically, four batteries 14 (e.g., 14a, 14b, 14c, 14d) are removably connected in parallel (e.g., via terminals 38 such as positive terminal 38a, negative terminal 38b) and may be arranged to provide power to vehicle 12 such as cranking power. One or more of batteries 14 may have a connector 34 and/or a BMS 16 (e.g., BMS 16a, 16b, 16c, 16d). In some embodiments, one BMS 16 may support one or more batteries 14. BD 20 may be configured to communicate (e.g., via communication interface 56) with each battery 14 (via BMS 16 and/or connector 34) and/or vehicle 12. For example, communication interface 56 may be configured to receive/transmit at least one parameter such as current (e.g., peak current, total current, etc.) of any battery 14 and/or ignition status of vehicle 12.

Further, BD 20 may include one or more sensors 64 (e.g., sensors 64a, 64b, 64c, 64d) which may be configured to connect via sensor connection 96 (e.g., sensor connection 96a, 96b, 96c, 96d) and/or measure at least one parameter such as such as current (e.g., peak current, total current, etc.) of any battery 14 (e.g., via connector 34, terminals 38, and/or BMS 16) and/or ignition status of vehicle 12 (e.g., via a connection to vehicle 12 such as to an ignition switch and/or other vehicle system configured to provide vehicle parameters). Any sensor 64 may be electrically connected to a terminal 38. For example, sensor 64 may be connected between one of terminals 38a, 38b and vehicle 12 (e.g., between one of terminals 38a, 38b and a starter motor of vehicle 12 or other systems of vehicle 12). BD 20 may be comprised in any of batteries 14 and/or BMS 16 and/or vehicle 12 or stand alone and removably connectable to any of batteries 14 and/or BMS 16 and/or vehicle 12.

In a nonlimiting example, any parameter (such as current, ignition status, etc.) may be used by BD 20 to determine a battery health condition (e.g., degraded state of health) of any one of the batteries 14 based on a parameter of a battery 14 such as when a difference (e.g., spread) between the peak current of battery 14a during cracking and the peak current of at least one other battery 14b, 14c, 14d is greater than a predetermined threshold. Further, BD 20 may determine (e.g., at least via sensors 64 and/or communication interface 56) that the total current of battery 14a indicates an overcharge when battery 14a should be discharging (e.g., when the ignition of vehicle 12 is off). The overcharge indication and/or spread may be used to determine that state of health of battery 14a is degraded. The variation of spread over time may be used to forecast degradation of battery health and/or schedule maintenance (e.g., via server 24).

Although batteries 14 are shown in parallel, the embodiments herein are not limited as such, i.e., batteries 14 may be connected in any other way such as in series, a combination of series and parallel, etc.

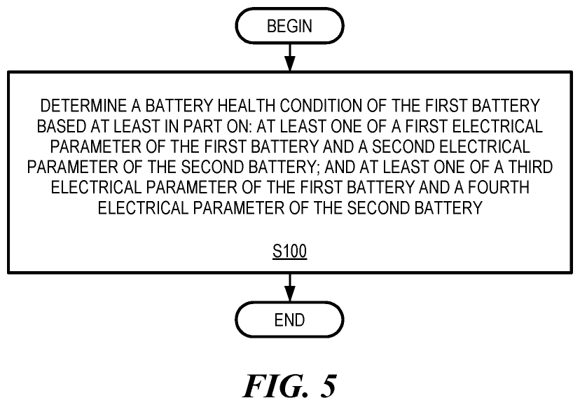

FIG. 5 is a flowchart of an example process (i.e., method) in BD 20 according to some embodiments of the present invention. One or more blocks described herein may be performed by one or more elements of BD 20 such as by one or more of processing circuitry 58 (including the BD BH unit 22), processor 60, and/or communication interface 56 and/or sensor 64. BD 20 is configured to determine (Block S100) a battery health condition of the first battery 14a based at least in part on: at least one of a first electrical parameter of the first battery 14a and a second electrical parameter of the second battery 14b; and at least one of a third electrical parameter of the first battery 14a and a fourth electrical parameter of the second battery 14b.

In some embodiments, the method further includes measuring the first and second electrical parameters. Each one of the first and second electrical parameters includes a first plurality of electrical parameter samples, and each electrical parameter sample of the first plurality of electrical parameter samples is measured during one cranking action.

In some other embodiments, the method further includes determining at least one of a first spread and a second spread, where each one of the first and second spreads is between the first electrical parameter and the second electrical parameter, and the first and second spreads correspond to a first interval of time and a second interval of time, respectively.

In an embodiment, the method further includes determining the battery health condition is a failure condition when the determined at least one of the first and second spreads exceed a predetermined threshold.

In another embodiment, the method further includes at least one of determining a spread rate of change based on the first spread and the second spread; forecasting the battery health condition is expected to occur in a future time interval based on the determined spread rate of change; and determining a maintenance action based on the determined spread rate of change and the forecast battery health condition.

In some embodiments, the method further includes measuring the third and fourth electrical parameter, where each one of the third and fourth electrical parameter includes a second plurality of electrical parameter samples, each electrical parameter of the second plurality of electrical parameter samples being measured while an ignition status is off.

In some other embodiments, the method further includes determining a battery charging condition of the first battery when the ignition status is off. The determined battery health condition is further based on the determined battery charging condition.

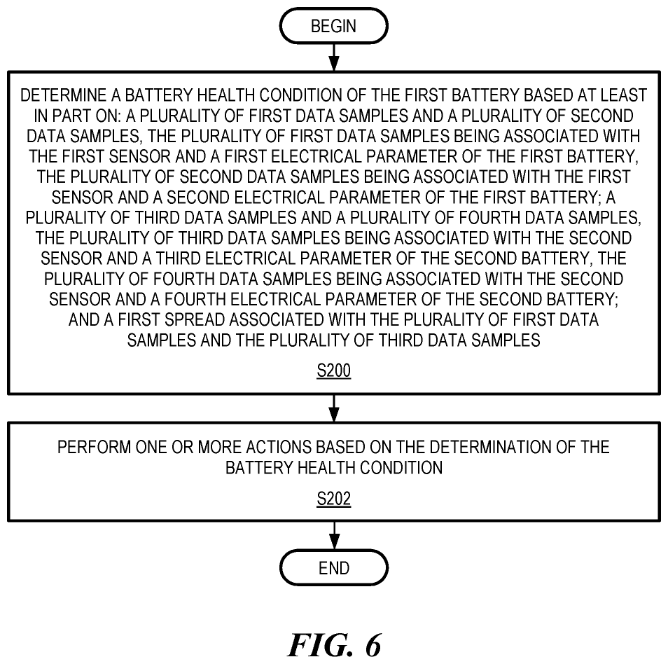

FIG. 6 is a flowchart of another example process (i.e., method) in battery device 20 according to some embodiments of the present invention. The battery device 20 is removably connectable at least to a first battery 14 and a second battery 14. The battery device 20 includes processing circuitry 58, a first sensor 64 and a second sensor 64. The first sensor 64 and the second sensor 64 are in communication with the processing circuitry 58. More specifically, one or more blocks described herein may be performed by one or more elements of BD 20 such as by one or more of processing circuitry 58 (including the BD BH unit 22), processor 60, and/or communication interface 56 and/or sensor 64. Battery device 20 is configured to determine (Block S200) a battery health condition of the first battery 14 based at least in part on: (A) a plurality of first data samples and a plurality of second data samples, where the plurality of first data samples is associated with the first sensor 64 and a first electrical parameter of the first battery 14, and the plurality of second data samples is associated with the first sensor 64 and a second electrical parameter of the first battery 14; (B) a plurality of third data samples and a plurality of fourth data samples, where the plurality of third data samples is associated with the second sensor 64 and a third electrical parameter of the second battery 14, and the plurality of fourth data samples is associated with the second sensor 64 and a fourth electrical parameter of the second battery 14; and (C) a first spread associated with the plurality of first data samples and the plurality of third data samples. Further, battery device 20 is configured to perform (Block S202) one or more actions based on the determination of the battery health condition.

In some embodiments, the method further includes performing, by the first sensor 64, one or more measurements of the first electrical parameter and the second electrical parameter of the first battery 14 and performing, by the second sensor 64, one or more measurements of and the fourth electrical parameter of the second battery 14.

In some other embodiments, the method further includes determining the plurality of first data samples based on the one or more measurements of the first electrical parameter, determining the plurality of second data samples based on the one or more measurements of the second electrical parameter, determining the plurality of third data samples based on the one or more measurements of the third electrical parameter, and determining the plurality of fourth data samples based on the one or more measurements of the fourth electrical parameter.

In some embodiments, the first electrical parameter and the third electrical parameter are measured during one cranking action.

In some other embodiments, the method further includes determining the first spread, the first spread being a difference between at least one first data sample of the plurality of first data samples and at least one third data sample of the plurality of third data samples.

In some embodiments, a first distribution density (e.g., determined as part of the method) of the at least one first data sample is greater than a first distribution density threshold, and a third distribution density (e.g., determined as part of the method) of the at least one third data sample is greater than a third distribution density threshold.

In some other embodiments, the method further includes determining the battery health condition of the first battery 14 further based on a second spread.

In some embodiments, the method further includes at least one of determining a first group of data samples of the plurality of second data samples that exceeds a predetermine electrical parameter threshold, determining a second group of data samples of the plurality of fourth data samples that exceeds the predetermine electrical parameter threshold, and determining the second spread. The second spread is between at least one data sample of the first group and another data sample of the second group.

In some other embodiments, the first group of data samples and the second group of data samples correspond to a first ignition status. The first ignition status is off.

In some embodiments, the method further includes determining a battery charging condition exists based on the second spread, where the battery charging condition is inconsistent with the first ignition status being off. The determined battery health condition is further based on the determined battery charging condition.

In some other embodiments, the method further includes at least one of comparing at least one data sample of the first group of data samples with at least one other data sample of at least one of the plurality of second data samples and the plurality of fourth data samples. The one other data sample corresponds to a second ignition status, and the second ignition status is on. The method also includes confirming that the battery health condition of the first battery exists based on the comparison, the battery charging condition, the first spread, and the second spread.

In some embodiments, the method further includes at least one of determining a first spread rate of change based on the first spread, determining a second spread rate of change based on the second spread, and forecasting the battery health condition is expected to occur within a future time interval based on at least one of the first spread rate of change and the second spread rate of change.

In some embodiments, performing the one or more actions includes at least one of determining a maintenance action to address the battery health condition, transmitting an indication of at least one of the battery health condition and the maintenance action, and causing a battery management system of the first battery to disable the first battery 14. In some other embodiments, the first electrical parameter of the first battery 14 is peak current, the second electrical parameter of the first battery 14 is battery total current, the third electrical parameter of the second battery 14 is peak current, and the fourth electrical parameter of the second battery 14 is battery total current.

Having described the general process flow of arrangements of the disclosure and having provided examples of hardware and software arrangements for implementing the processes and functions of the disclosure, the sections below provide details and examples of arrangements for one or more process related to predicting of a battery health condition (e.g., battery issue) such as of a vehicle 12 with multiple batteries 14. Although, for ease of understanding, one or more embodiments are described with respect to parameters (e.g., current such as peak current, total current, etc.), the embodiments of the present disclosure are not limited as such and may include any other parameters such as voltage, peak voltage, total voltage, dropped voltage, etc.

In some embodiments, at least one parameter (e.g., data) of each battery 14 of a vehicle 12 such as a truck is determined. The vehicle 12 may include more than one battery 14. In some other embodiments, the at least one parameter (e.g., data) includes an electrical parameter (e.g., peak current, voltage) of each battery 14 during cranking. When all batteries 14 are healthy, each battery 14 contribute a similar amount of the parameter (e.g., current, voltage) during cranking. If one battery 14 starts to fail, its parameter (e.g., peak current, voltage) drops (e.g., below a threshold), while the parameter (e.g., peak current, peak voltage) of other batteries 14 increase. That is, there is a separation (e.g., spread) between the parameter (e.g., peak current, voltage) of the battery 14 that starts to fail and the rest of the batteries 14 of vehicle 12. The spread may be determined between any data point/sample of one curve or group of data points/samples and any other data point/sample of another curve or another group of data points/samples. Further, by measuring the speed of separation (i.e., the rate at which the separation/spread changes over time), battery health conditions such as battery issues may be predicted.

In an embodiment, the measurements are performed in the field (e.g., while vehicle 12 and/or batteries 14 are being used) and/or parameters such as field data of each battery 14 and vehicle 12 can be used to predict more reliably (e.g., than existing technology) the status of each battery and/or probability of vehicle issues (e.g., because of batteries issues). In another embodiment, at least one parameter such as the battery peak current data and/or peak voltage data during cranking is used to determine the battery health condition. In some other embodiments, a connected battery platform is not needed.

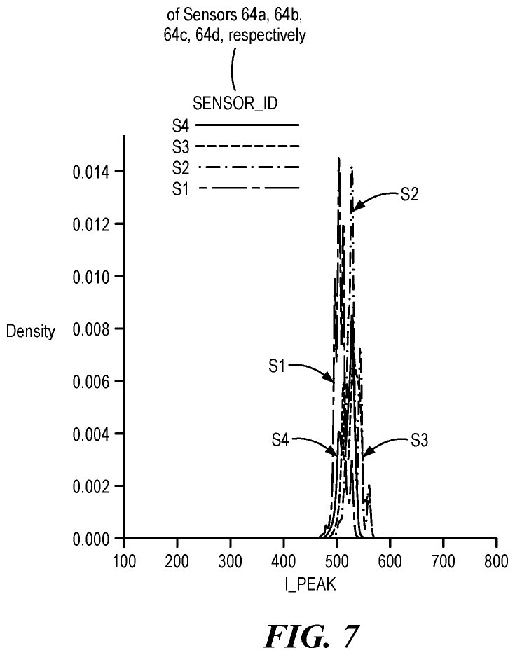

FIG. 7 shows a distribution chart of example peak current during cranking when all batteries are healthy according to some embodiments of the present disclosure. The x-axis corresponds to the value of peak current (i.e., I_PEAK), and the y-axis corresponds to the probability density (e.g., how likely a peak current value is to occur, be observed/measured, etc.). Four curves are shown, each one corresponding to measurements (data samples) from one sensor 64. Each sensor 64 may have an identifier (i.e., SENSOR_ID) such as S1, S2, S3, S4. For example, first sensor 64a (S1) may correspond to a first battery 14a, second sensor 64b (S2) may correspond to a second battery 14b, third sensor 64b (S3) may correspond to a third battery 14c, and sensor 64d (S4) may correspond to a fourth battery 14d. The curves indicate that the peak current during cranking (for all batteries 14 and/or sensors 64) spread between 450 amps and 650 amps. The curves and/or data points (data samples) of FIG. 6 may be an indication that all four batteries 14a, 14b, 14c, and 14d are healthy (e.g., battery heath condition is healthy, good, not degraded, etc.).

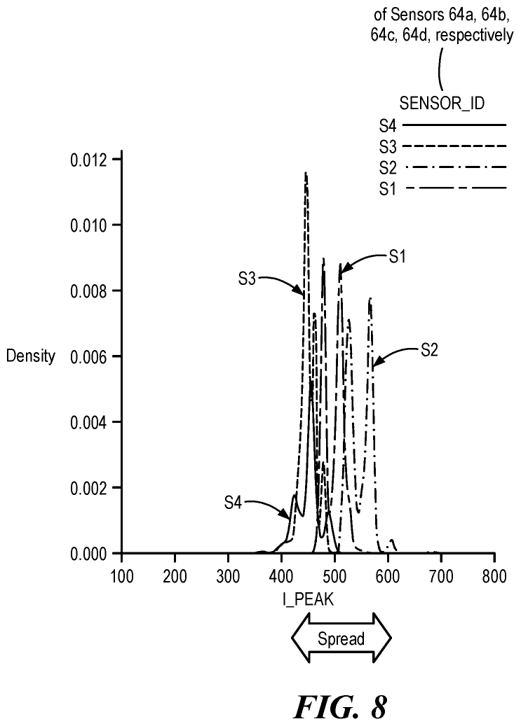

FIG. 8 shows another distribution chart of example peak current during cranking where early signs of battery issues are detected by BD 20 according to some embodiments of the present disclosure. The x-axis and y-axis in FIG. 8 are the same as those in FIG. 7. Four curves are shown, each one corresponding to measurements (data samples) from one sensor 64 (e.g., first sensor 64a corresponding to a first battery 14a, second sensor 64b corresponding to a second battery 14b, third sensor 64c corresponding to a third battery 14c, 64d corresponding to a fourth battery 14d). The curves indicate that the peak current during cranking for all batteries 14 and/or sensors 64 spread between 350 amps and 700 amps. When compared to FIG. 7, each curve of FIG. 8 has spread apart from each other. The curves and/or data points (data samples) of FIG. 8 may be an indication of early signs of issues at least in one of the four batteries 14a, 14b, 14c, and 14d (e.g., battery heath condition may not be healthy, has started to degrade, etc.).

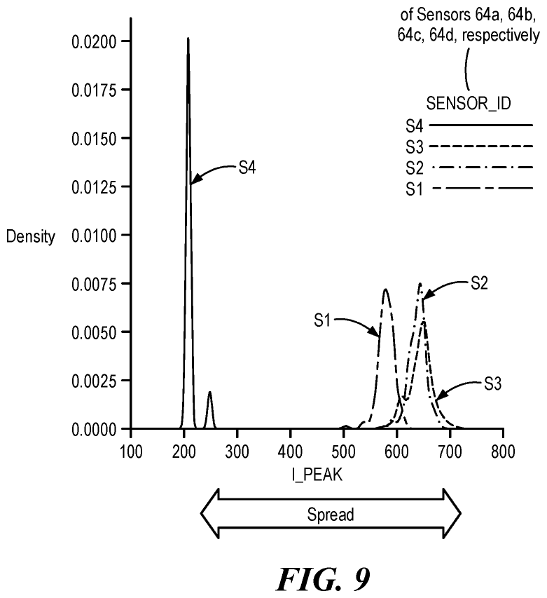

FIG. 9 shows another distribution chart of example peak current during cranking where battery issues are detected by BD 20 according to some embodiments of the present disclosure. The x-axis and y-axis in FIG. 8 are the same as in FIGS. 7 and 8. Four curves are shown, each one corresponding to measurements (data samples) from one sensor 64 (e.g., first sensor 64a corresponding to a first battery 14a, second sensor 64b corresponding to a second battery 14b, third sensor 64c corresponding to a third battery 14c, 64d corresponding to a fourth battery 14d). The curves indicate that the peak current during cranking for all batteries 14 and/or sensors 64 spread between 180 amps and 750 amps. When compared to FIGS. 6 and 7, the curve corresponding to sensor 64d (e.g., S4) has spread (e.g., separated) from the curves corresponding to sensors 64a (e.g., S1), 64b (e.g., S2), 64c (e.g., S3). That is, the curve corresponding sensor 64d (e.g., S4) indicates that battery 14d provides less peak current (e.g., approximately between 180 amps and 270 amps) during cranking than the peak current during cranking provided by batteries 14a, 14b, 14c (as shown by the curves corresponding to 64a (e.g., S1), 64b (e.g., S2), 64c (e.g., S3)). The spread and/or spread over time and/or the probability density and/or the peak current values may be used to determine that battery 14d is experiencing an issue (i.e., battery heath condition may be not healthy, degrade, etc.). In some cases, all four batteries 14a, 14b, 14c, 14d may still provide sufficient power for starting and/or operating vehicle 12. In other words, the issue of battery 14d may go undetected by an operator of vehicle 12 until there is a catastrophic battery failure of battery 14d (e.g., if one or more embodiments of the present disclosure are not employed).

FIG. 10 shows a distribution chart of example battery total current when all batteries are healthy and the ignition status of vehicle 12 is off according to some embodiments of the present disclosure. The x-axis corresponds to the value of total battery current (i.e., I_BATT_TOTAL), and the y-axis corresponds to the probability density (e.g., how likely a total battery current value is to occur, be observed/measured, etc.). Four curves are shown when the ignition status is off (i.e., IGNSTATUS=0.0).

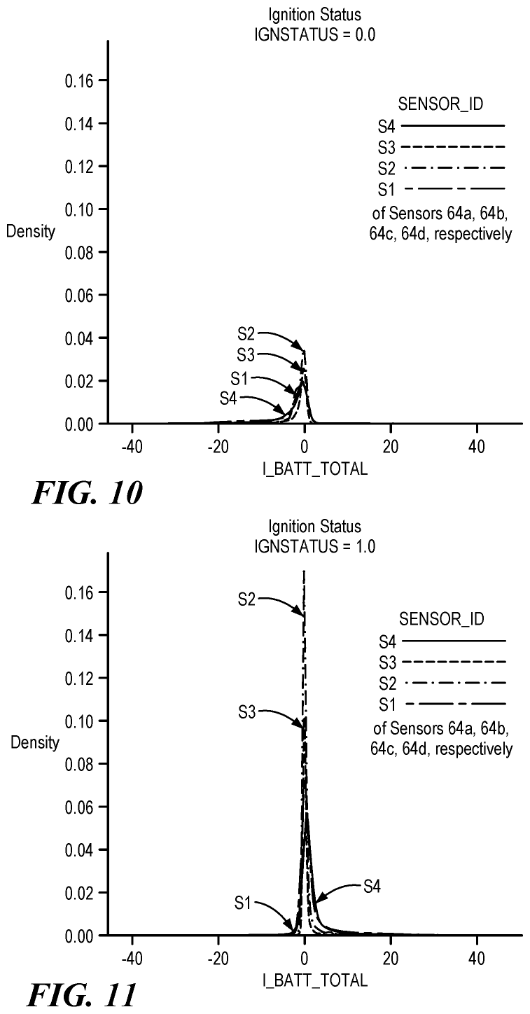

FIG. 11 shows the distribution chart of example battery total current when all batteries are healthy and the ignition status of vehicle 12 is on according to some embodiments of the present disclosure. The x-axis corresponds to the value of total battery current (i.e., I_BATT_TOTAL), and the y-axis corresponds to the probability density (e.g., how likely a total battery current value is to occur, be observed/measured, etc.). Four curves are shown when the ignition status is on (i.e., IGNSTATUS=1.0). Each curve (of each the charts of FIGS. 10 and 11) corresponds to measurements (data samples) from one sensor 64 (e.g., first sensor 64a corresponding to a first battery 14a, second sensor 64b corresponding to a second battery 14b, third sensor 64c corresponding to a third battery 14c, 64d corresponding to a fourth battery 14d). When the ignition is off, the curves spread between approximately −22 amps to +3 amps (i.e., each curve having a greater portion indicating negative current (or discharging) than positive current, which is consistent with the ignition being off). When the ignition is on, the curves spread between approximately −3 amps to +38 amps (i.e., each curve having a greater portion indicating positive current (or/charging) than negative current, which is consistent with the ignition being on). The curves and/or data points (data samples) of FIGS. 10 and 11 may be an indication that all batteries 14 are healthy.

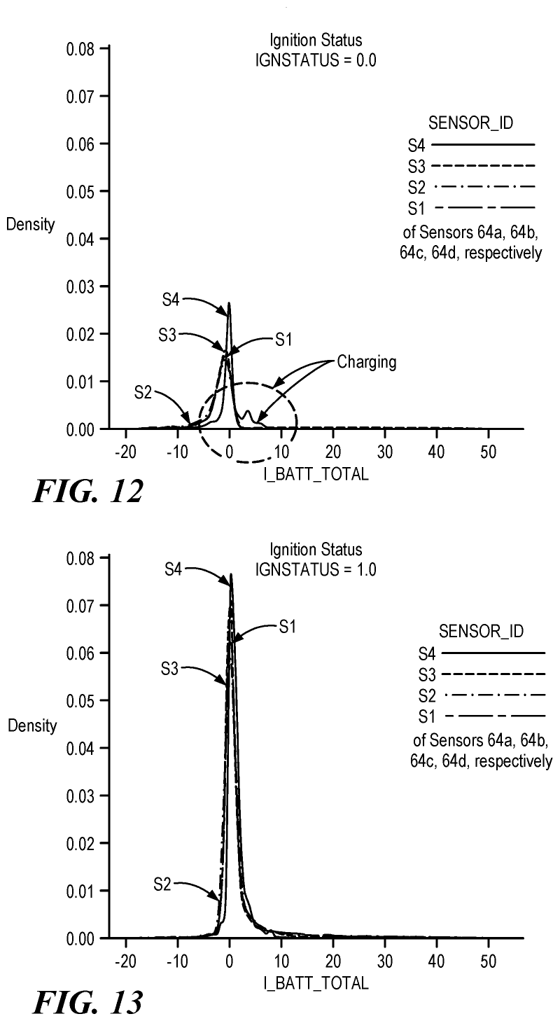

FIG. 12 shows a distribution chart of example battery total current when the ignition is off and at least one battery has an issue according to some embodiments of the present disclosure. FIG. 13 shows the distribution chart of example battery total current when the ignition is on and at least one battery has an issue according to some embodiments of the present disclosure. FIG. 12 is similar to FIG. 10, and FIG. 13 is similar to FIG. 11 When the ignition status is off (i.e., IGNSTATUS=0.0), the curve shown in FIG. 12 corresponding to sensor 64d (and battery 14d) includes a portion that spreads between 0 and at least +10 amps, which indicates a charging event of battery 14d. However, this is inconsistent with the ignition status being off, i.e., when the battery is not being charged. The indication that battery 14d appears to be charging while the ignition is off may be used to determine (and/or corroborate) the battery health condition of battery 14d identified in FIG. 9.

In one nonlimiting example, a vehicle 12 (e.g., truck) has four batteries 14a, 14b, 14c, 14d, and the first battery 14a may be developing a battery health condition. More specifically, vehicle 12 and/or batteries 14 may be integrated with (and/or removably connected to and/or in communication with) at least one of BMS 16, BD 20, and server 24 (e.g., wirelessly). Server 24 may be configured to communicate with any component of system 10 and/or receive an indication that a battery 14, e.g., one or more of batteries 14a-14d, is experiencing a battery health condition and/or automatically schedule a corresponding maintenance appointment at a service center.

BD 20 may be configured to determine a health condition of the first battery 14a based on peak current and/or total current. For example, when the peak current of the first battery 14a has spread (and/or separated) from the peak current corresponding to the other batteries 14b, 14c, 14d beyond a predetermined threshold, BD 20 determines that a degraded battery health condition of battery 14a has been detected, which may be corroborated by determining that the total battery current corresponding to the first battery 14a shows an overcharge condition (i.e., total battery current greater than 0, total current greater than a positive threshold, etc.) when the ignition is off. Even if the four batteries still provide sufficient power to start and operate vehicle 12 (i.e., operator of vehicle 12 may be unaware of battery issue), BD 20 may send an indication that battery 14 is experiencing a battery health condition.

The operator of vehicle 12 may be alerted of the battery heath condition of battery 14a, e.g., via server 24 which may indicate that a maintenance issue has been identified with battery 14a and/or that a replacement of battery 14a has been scheduled at a service center. Further, by comparing the change in spread (between the curve of peak current of battery 14a and the remaining batteries 14b, 14c, 14d) throughout time (e.g., weekly), BD 20 may forecast (and/or predict) when battery 14a will have a failure (e.g., a catastrophic failure, a failure that will not allow vehicle to be started/operated, etc.).

In other words, the embodiments of the present disclosure are beneficial at least because battery health conditions (e.g., issues) may be determined before a catastrophic failure of the battery occurs and/or an expected date/time when the catastrophic failure may occur may be determined, e.g., so that the battery may be replaced and the interruption for replacing the battery is minimized. That is, a longer interruption in the operation of the vehicle 12 and/or battery 14 associated with a catastrophic failure is avoided.

As will be appreciated by one of skill in the art, the concepts described herein may be embodied as a method, data processing system, computer program product and/or computer storage media storing an executable computer program. Accordingly, the concepts described herein may take the form of an entirely hardware embodiment, an entirely software embodiment or an embodiment combining software and hardware aspects all generally referred to herein as a “circuit” or “module.” Any process, step, action and/or functionality described herein may be performed by, and/or associated to, a corresponding module, which may be implemented in software and/or firmware and/or hardware. Furthermore, the disclosure may take the form of a computer program product on a tangible computer usable storage medium having computer program code embodied in the medium that can be executed by a computer. Any suitable tangible computer readable medium may be utilized including hard disks, CD-ROMs, electronic storage devices, optical storage devices, or magnetic storage devices.

Some embodiments are described herein with reference to flowchart illustrations and/or block diagrams of methods, systems and computer program products. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer (to thereby create a special purpose computer), special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable memory or storage medium that can direct a computer or other programmable data processing apparatus to function in a particular manner, such that the instructions stored in the computer readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved. Although some of the diagrams include arrows on communication paths to show a primary direction of communication, it is to be understood that communication may occur in the opposite direction to the depicted arrows.

Computer program code for carrying out operations of the concepts described herein may be written in an object oriented programming language such as Python, Java® or C++. However, the computer program code for carrying out operations of the disclosure may also be written in conventional procedural programming languages, such as the “C” programming language. The program code may execute entirely on the user's computer, partly on the user's computer, as a stand-alone software package, partly on the user's computer and partly on a remote computer or entirely on the remote computer. In the latter scenario, the remote computer may be connected to the user's computer through a local area network (LAN) or a wide area network (WAN), or the connection may be made to an external computer (for example, through the Internet using an Internet Service Provider).

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

It will be appreciated by persons skilled in the art that the present embodiments are not limited to what has been particularly shown and described herein above. In addition, unless mention was made above to the contrary, it should be noted that all of the accompanying drawings are not to scale. A variety of modifications and variations are possible in light of the above teachings and the following claims.

1. A battery device removably connectable at least to a first battery and a second battery, the battery device comprising processing circuitry, a first sensor and a second sensor, the first sensor and the second sensor being in communication with the processing circuitry, the processing circuitry being configured to:
determine a battery health condition of the first battery based at least in part on:
a plurality of first data samples and a plurality of second data samples, the plurality of first data samples being associated with the first sensor and a first electrical parameter of the first battery, the plurality of second data samples being associated with the first sensor and a second electrical parameter of the first battery;
a plurality of third data samples and a plurality of fourth data samples, the plurality of third data samples being associated with the second sensor and a third electrical parameter of the second battery, the plurality of fourth data samples being associated with the second sensor and a fourth electrical parameter of the second battery; and
a first spread associated with the plurality of first data samples and the plurality of third data samples; and
perform one or more actions based on the determination of the battery health condition.

2. The battery device of claim 1, wherein:
the first sensor is configured to:
perform one or more measurements of the first electrical parameter and the second electrical parameter of the first battery; and
the second sensor is configured to:
perform one or more measurements of and the fourth electrical parameter of the second battery.

3. The battery device of claim 2, wherein the processing circuitry is further configured to:
determine the plurality of first data samples based on the one or more measurements of the first electrical parameter;
determine the plurality of second data samples based on the one or more measurements of the second electrical parameter;
determine the plurality of third data samples based on the one or more measurements of the third electrical parameter; and
determine the plurality of fourth data samples based on the one or more measurements of the fourth electrical parameter.

4. The battery device of claim 2, wherein the first electrical parameter and the third electrical parameter are measured during one cranking action.

5. The battery device of claim 1, wherein the processing circuitry is further configured to:
determine the first spread, the first spread being a difference between at least one first data sample of the plurality of first data samples and at least one third data sample of the plurality of third data samples.

6. The battery device of claim 5, wherein a first distribution density of the at least one first data sample is greater than a first distribution density threshold, and a third distribution density of the at least one third data sample is greater than a third distribution density threshold.

7. The battery device of claim 1, wherein the processing circuitry is further configured to:
determine the battery health condition of the first battery further based on a second spread.

8. The battery device of claim 7, wherein the processing circuitry is further configured to at least one of:
determine a first group of data samples of the plurality of second data samples that exceeds a predetermine electrical parameter threshold;
determine a second group of data samples of the plurality of fourth data samples that exceeds the predetermine electrical parameter threshold; and
determine the second spread, the second spread being between at least one data sample of the first group and another data sample of the second group.

9. The battery device of claim 8, wherein the first group of data samples and the second group of data samples correspond to a first ignition status, the first ignition status being off.

10. The battery device of claim 9, wherein the processing circuitry is further configured to:
determine a battery charging condition exists based on the second spread, the battery charging condition being inconsistent with the first ignition status being off, the determined battery health condition being further based on the determined battery charging condition.

11. The battery device of claim 9, wherein the processing circuitry is further configured to at least one of:
compare at least one data sample of the first group of data samples with at least one other data sample of at least one of the plurality of second data samples and the plurality of fourth data samples, the one other data sample corresponding to a second ignition status, the second ignition status being on; and
confirm that the battery health condition of the first battery exists based on the comparison, the battery charging condition, the first spread, and the second spread.

12. The battery device of claim 7, wherein the processing circuitry is further configured to at least one of:
determine a first spread rate of change based on the first spread;
determine a second spread rate of change based on the second spread; and
forecast the battery health condition is expected to occur within a future time interval based on at least one of the first spread rate of change and the second spread rate of change.

13. The battery device of claim 7, wherein performing the one or more actions includes at least one of:
determining a maintenance action to address the battery health condition;
transmitting an indication of at least one of the battery health condition and the maintenance action; and
causing a battery management system of the first battery to disable the first battery.

14. The battery device of claim 1, wherein:
the first electrical parameter of the first battery is peak current;
the second electrical parameter of the first battery is battery total current;
the third electrical parameter of the second battery is peak current; and
the fourth electrical parameter of the second battery is battery total current.

15. A method in a battery device removably connectable at least to a first battery and a second battery, the battery device comprising a first sensor and a second sensor, the method comprising:
determining a battery health condition of the first battery based at least in part on:
a plurality of first data samples and a plurality of second data samples, the plurality of first data samples being associated with the first sensor and a first electrical parameter of the first battery, the plurality of second data samples being associated with the first sensor and a second electrical parameter of the first battery;
a plurality of third data samples and a plurality of fourth data samples, the plurality of third data samples being associated with the second sensor and a third electrical parameter of the second battery, the plurality of fourth data samples being associated with the second sensor and a fourth electrical parameter of the second battery; and
a first spread associated with the plurality of first data samples and the plurality of third data samples; and
performing one or more actions based on the determination of the battery health condition.

16. The method of claim 15, wherein the method further includes:
performing, by the first sensor, one or more measurements of the first electrical parameter and the second electrical parameter of the first battery;
performing, by the second sensor, one or more measurements of the third electrical parameter and the fourth electrical parameter of the second battery;
determining the plurality of first data samples based on the one or more measurements of the first electrical parameter;
determining the plurality of second data samples based on the one or more measurements of the second electrical parameter;
determining the plurality of third data samples based on the one or more measurements of the third electrical parameter; and
determining the plurality of fourth data samples based on the one or more measurements of the fourth electrical parameter; and
wherein the first electrical parameter and the third electrical parameter are measured during one cranking action.

17. (canceled)

18. (canceled)

19. The method of claim 15, the method further includes:
determining the first spread, the first spread being a difference between at least one first data sample of the plurality of first data samples and at least one third data sample of the plurality of third data samples, wherein a first distribution density of the at least one first data sample is greater than a first distribution density threshold, and a third distribution density of the at least one third data sample is greater than a third distribution density threshold.

20. (canceled)

21. The method of claim 15, wherein the method further includes:
determining the battery health condition of the first battery further based on a second spread and at least one of:
determining a first group of data samples of the plurality of second data samples that exceeds a predetermine electrical parameter threshold;
determining a second group of data samples of the plurality of fourth data samples that exceeds the predetermine electrical parameter threshold; and
determining the second spread, the second spread being between at least one data sample of the first group and another data sample of the second group; and
wherein the first group of data samples and the second group of data samples correspond to a first ignition status, the first ignition status being off.

22. (canceled)

23. (canceled)

24. The method of claim 21, wherein the method further includes:
determining a battery charging condition exists based on the second spread, the battery charging condition being inconsistent with the first ignition status being off, the determined battery health condition being further based on the determined battery charging condition;
at least one of:
comparing at least one data sample of the first group of data samples with at least one other data sample of at least one of the plurality of second data samples and the plurality of fourth data samples, the one other data sample corresponding to a second ignition status, the second ignition status being on; and
confirming that the battery health condition of the first battery exists based on the comparison, the battery charging condition, the first spread, and the second spread;
determining a first spread rate of change based on the first spread;
determining a second spread rate of change based on the second spread; and
forecasting the battery health condition is expected to occur within a future time interval based on at least one of the first spread rate of change and the second spread rate of change.

25. (canceled)

26. (canceled)

27. The method of claim 21, wherein performing the one or more actions includes at least one of:
determining a maintenance action to address the battery health condition;
transmitting an indication of at least one of the battery health condition and the maintenance action; and
causing a battery management system of the first battery to disable the first battery; and
wherein:
the first electrical parameter of the first battery is peak current;
the second electrical parameter of the first battery is battery total current;
the third electrical parameter of the second battery is peak current; and
the fourth electrical parameter of the second battery is battery total current.

28.-30. (canceled)
